(19) United States
(12) Patent Application Publication
(10) Pub. No.: US 2025/0046568 A1
(43) Pub. Date: Feb. 6, 2025

(54) SEM NAVIGATION BY FOCUSED ION BEAM SYSTEM WITH CRYO COOLING SAMPLE STAGE

(71) Applicant: FEI Company, Hillsboro, OR (US)

(72) Inventors: Libor Strakoš, Brno (CZ); Michal Geryk, Brno (CZ); Trevan Landin, Twisp, WA (US); Zdenêk Král, Eindhoven (NL); YoonHae Kim, Suwon (KR); Pengfu Hsu, College Station, TX (US)

(21) Appl. No.: 18/789,391

(22) Filed: Jul. 30, 2024

Related U.S. Application Data
(60) Provisional application No. 63/516,837, filed on Jul. 31, 2023.
(60) Provisional application No. 63/516,838, filed on Jul. 31, 2023.

(51) Int. Cl. H01J 37/20; H01J 37/28

(52) U.S. Cl. CPC H01J 37/20; H01J 37/28; H01J 2237/002; H01J 2237/2448; H01J 2237/31749

(57) ABSTRACT

Embodiments of an analytical instrument system, components, and methods for preparing dose-sensitive samples for microanalysis are described. A method includes receiving location data for a material sample, locating a region of interest (ROI) of the material sample in reference to the location data, cooling the material sample to a cryogenic temperature, depositing a layer over at least a portion of the ROI at the cryogenic temperature, and removing a portion of the material sample at the cryogenic temperature.

### CROSS REFERENCE TO RELATED APPLICATIONS

This application claims the benefit of priority to provisional application No. 63/516,837, entitled, “SEM NAVIGATION BY FOCUSED ION BEAM WITH CRYO COOLING SAMPLE STAGE,” filed on Jul. 31, 2023 and to provisional application No. 63/516,838, entitled, “SEMI-AUTOMATED SLICE-AND-VIEW BY CRYO-FIB/EM (SEM AND S/TEM) FOR DEVICE-LINE END-POINTING WITH BEAM SENSITIVE MATERIALS,” filed on Jul. 31, 2023, the disclosure of which is hereby incorporated by reference in its entirety.

### TECHNICAL FIELD

Embodiments of the present disclosure are directed to charged particle microscope systems, as well as algorithms and methods for their operation. In particular, some embodiments are directed toward techniques for preparing dose-sensitive samples.

### BACKGROUND

Photoresist (PR) profiles tend to have deformation and shrinkage with conventional Transmission electron microscopy (TEM) sample preparation method using Scanning Electron Microscope (SEM) and Focused Ion Beam (FIB). The increasing temperature during the TEM sample preparation may affect the deformation and shrinkage with PR profiles. The technique using Scanning Electron Microscope (SEM) and Focused Ion Beam (FIB) has been widely adopted for Transmission electron microscopy (TEM) sample preparation method. However, there is some issues such as deformation and shrinkage of photoresist (PR) profiles with conventional TEM sample preparation method using SEM and FIB. It has been known that PR is fragile and extremely sensitive to temperature. The rising temperature during the TEM sample preparation may cause PR deformation and shrinkage. Therefore, it has been employed several coating methods, such as atomic layer deposition coating or ink coating to reduce deformation.

### BRIEF SUMMARY

In the forthcoming paragraphs, embodiments of an analytical instrument system, components, and methods for preparing dose-sensitive samples for microanalysis are described. In a first aspect, a method, includes receiving location data for a material sample, locating a region of interest (ROI) of the material sample in reference to the location data, cooling the material sample to a cryogenic temperature, depositing a layer over at least a portion of the ROI at the cryogenic temperature, and removing a portion of the material sample at the cryogenic temperature.

In some embodiments, the material sample can include a photoresist. The photoresist can be or include a material suitable as a photoresist for extreme ultraviolet (EUV) photons. The material sample can include an anti-reflective coating (ARC) disposed between the photoresist and a substrate. Depositing the layer can include introducing a precursor into an environment of the material sample. The precursor can include a metal substituent. Decomposing the precursor can use a focused beam of charged particles. The metal can be or include platinum or tungsten. The precursor can be or include (methylcyclopentadienyl)trimethyl platinum. The charged particles can be ions. The method can further include hardening the layer using a focused ion beam.

Locating the ROI can include include not exposing the material sample to a beam of electrons. Locating the ROI can includes generating an optical microscope image of the material sample. Locating the ROI can include generating secondary electron detector data at a relatively low magnification setting of an electron beam system, where the relatively low magnification setting corresponds to a magnification setting and a beam current setting that together render visible a reference feature in the location data. Locating the ROI can include executing a registered movement of the sample stage, based at least in part on the location data, where a location of the ROI can be described in reference to a reference feature on the sample. In some embodiments, the location data can include computer-aided-drafting (CAD) data describing at least a portion of the material sample and a location of the ROI. In some embodiments, locating the ROI can follow cooling the sample to the cryogenic temperature.

The cryogenic temperature can be about −170° C. The method can include maintaining a temperature differential between the material sample and a cold reservoir, such that the material sample is relatively warmer than the cold reservoir by about 20° C.

Removing a portion of the material sample can include milling the material sample to form a lamella. The method can further include lifting out the lamella sample and thinning the lamella sample. The method can further include generating an image of a cross-surface of the material sample using a charged particle microscope, the cross surface being at an angle relative to a lateral surface of the sample. The image can be generated while the material sample is at the cryogenic temperature.

In a second aspect, a charged particle beam system includes control circuitry and one or more non-transitory machine-readable storage media, operably coupled with the control circuitry, storing instructions. The instructions, when executed by one or more components of the system or other machine(s), cause the system to perform operations of the methods of the preceding aspect in one or more embodiments.

In a third aspect, a system includes a vacuum chamber, an electron microscope column operably coupled with the vacuum chamber, and a focused ion beam column operably coupled with the vacuum chamber. The system includes a sample stage disposed in the vacuum chamber and a cooling system, thermally coupled with the sample stage and configured to cool the sample stage to cryogenic temperatures. The system can be configured to implement the method of the preceding aspects in one or more embodiments.

The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims. For example, the preceding aspects and various embodiments can be combined with one or more other aspects and/or embodiments of the same or other aspects.

### BRIEF DESCRIPTION OF THE SEVERAL VIEWS OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example dual-beam system, in accordance with some embodiments of the present disclosure.

FIG. 2 is a block flow diagram illustrating an example process for preparation of a sample, in accordance with some embodiments of the present disclosure.

FIG. 3 is an electron micrograph of a TEM sample preparation area, in accordance with an example embodiment of the present disclosure.

FIGS. 4A-4F is a set of electron micrographs of a sample preparation procedure using an ambient temperature FIB process without SEM deposition (split 1). (A) GIS Pt blind deposition on the sample and bulk milling; (B) U-cut; (C) Needle attachment with ROI deposition; (D) Lift-out lamella; (E) Lamella attachment with ROI deposition; (F) Thinning on grid, in accordance with an example embodiment of the present disclosure.

FIGS. 5A-5F is a set of electron micrographs of a sample preparation procedure using partial cryo-FIB process without SEM deposition (split 2). (A) ambient temperature GIS Pt “blind” deposition on the sample; (B) bulk milling at cryogenic temperatures; (C) U-cut and GIS-free needle attachment; (D) Lift-out lamella. (E) GIS-free lamella attachment; and (F) Thinning on grid, in accordance with an example embodiment of the present disclosure.

FIG. 6 is a composite schematic diagram including an electron micrograph and a milling pattern overlay illustrating ROI free attachment using redeposition from milling at cryogenic temperatures, in accordance with an example embodiment of the present disclosure.

FIGS. 7A-7F is a set of electron micrographs of a sample preparation procedure using cryo-FIB process without SEM deposition (split 3). (A) cryogenic temperature GIS Pt “blind” deposition on the sample at cryogenic temperatures; (B) bulk milling at cryogenic temperatures; (C) U-cut and GIS-free needle attachment; (D) Lift-out lamella. (E) GIS-free lamella attachment; and (F) Thinning on grid, in accordance with an example embodiment of the present disclosure.

FIG. 8 is a composite schematic diagram including an electron micrograph and a measurement overlay illustrating a cross-section image of deposition in −170° C., in accordance with an example embodiment of the present disclosure.

FIGS. 9A-9D is a set of electron micrographs illustrating TEM images for PR profile analysis by using different TEM sample preparation conditions. (A) FIB process in ambient temperature including SEM deposition; (B) FIB process in ambient temperature without SEM deposition; (C) Partial Cryo-FIB process without SEM deposition: FIB deposition in ambient temperature and TEM sample preparation at cryogenic temperature; (D) Full Cryo-FIB process at cryogenic conditions without SEM deposition, in accordance with an example embodiment of the present disclosure.

FIGS. 10A-10D illustrate measurement data for the TEM image set of FIGS. 9A-9D, including a reference schematic diagram in FIG. 10A, in accordance with an example embodiment of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While illustrative embodiments have been illustrated and described, it will be appreciated that various changes can be made therein without departing from the spirit and scope of the disclosure. In the forthcoming paragraphs, embodiments of an analytical instrument system, components, and methods for preparing dose-sensitive samples for microanalysis are described. Embodiments of the present disclosure focus on semiconductor material samples and charged particle instruments for preparing such samples for transmission electron microscope (TEM) analysis in the interest of simplicity of description. To that end, embodiments are not limited to such samples, but rather are contemplated for samples for which constituent materials exhibit elevated sensitivity to energetic electrons. Similarly, while embodiments of the present disclosure focus on extreme ultraviolet (EUV) photoresist materials and consequent sensitivity of material samples to conventional TEM lamella preparation methods, additional and/or alternative samples are contemplated, which are deformed, damaged, or otherwise destructively modified by such conventional methods.

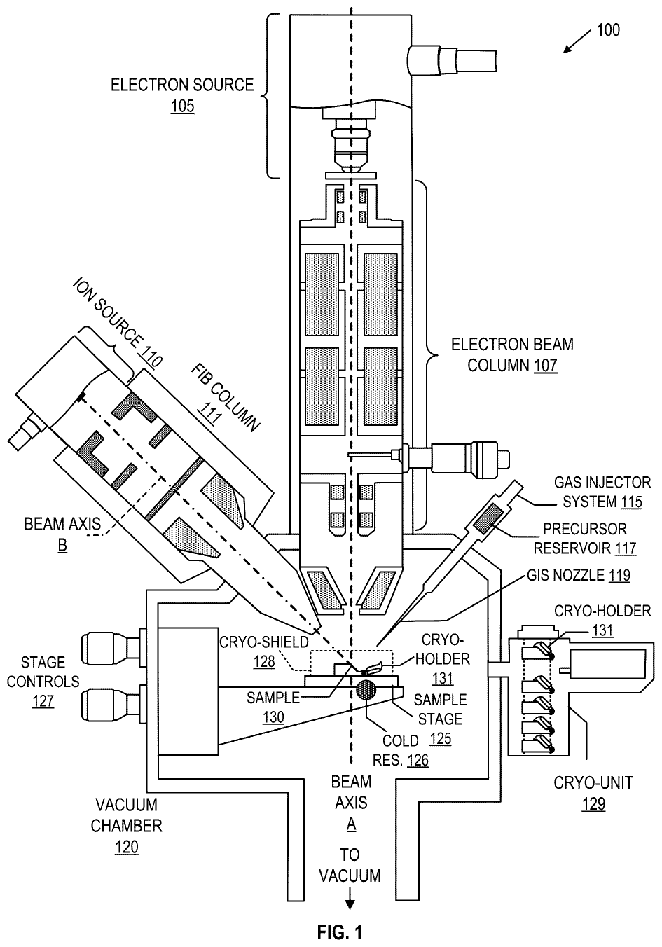

FIG. 1 is a schematic diagram illustrating an example dual-beam system 100, in accordance with some embodiments of the present disclosure. The example system 100 includes an electron source 105, an electron beam column 107, an ion source 110, a focused ion beam (“FIB”) column 111, a gas injection system (“GIS”) 115, a vacuum chamber 120, and a sample stage 125. The electron beam column 107 is illustrated as a scanning electron microscope (SEM) column, such that the example system 100 corresponds to a dual beam FIB-SEM system. The electron beam column 107, the FIB column 111, and the GIS 115 are illustrated as being operably coupled with the vacuum chamber 120, with the electron beam column 107 defining a first beam axis A and the FIB column 111 defining a second beam axis B. The axes A and B are illustrated converging onto a region of a sample 130, with the GIS 115 oriented toward the region of the sample 130 and configured to direct a gas stream including a precursor into the vacuum chamber. Advantageously, while axes A and B can also be oriented toward different locations, convergence permits the SEM system to image the region of the sample being processed by the FIB.

The electron source 105 can include one or more emitters configured to generate free electrons and to direct the electrons into the electron beam column 107. The emitters can include thermionic emitters, Schottky emitters, field-emission source emitters, or combinations thereof, operably coupled to power systems configured to apply a high-voltage (e.g., on the order of kilovolts to hundreds of kilovolts) to an emission region of the emitter material. For example, the electron source 105 can include a lanthanum hexaboride (LaB₆) emitter crystal to which a high electrical potential is applied to elicit the emission of electrons from a tip of the emitter crystal. In this way, a beam of electrons can be directed into the electron beam column 107.

The electron beam column 107 includes electromagnetic optics (e.g., electrostatic lenses, electromagnetic lenses, monochromators, aberration correctors, etc.) and apertures configured to shape, focus, defocus, narrow, and/or direct the beam of electrons such that the beam is focused onto the sample 130, in accordance with a set of operating parameters. The operating parameters can include a beam current, a beam energy (e.g., in volts, in electron volts, or the like), a magnification parameter, a scan pattern, a dwell time, and/or one or more pulse parameters. In this way, the example system 100 can function as an SEM to image portions of the sample 130 and/or can be used for e-beam assisted deposition of material onto the sample 130 (e.g., in coordination with the GIS 115) or other sample modifications.

The ion source 110 can include one or more components configured to generate a beam of ions and to direct the ions into the FIB column 111. In general, the ions can include metal ions and/or nonmetal ions (e.g., noble gas, halogen, oxygen, nitrogen, or the like). To that end, the ion source 110 can include a plasma source (e.g., an inductively coupled plasma source, a hollow cathode source, etc.) and/or a metal ion source (e.g., a liquid-metal gallium source). To that end, embodiments of the present disclosure are directed at systems, components, and methods for processing material samples using a beam of ions generated in the ion source 110. In some embodiments, the ion source 110 includes a plasma system for which atomic and/or molecular gases and their mixtures can serve as plasma precursor gases, from which a stream of ions can be extracted. The composition of ion beams can be suited to a given purpose, such as material removal (also referred to as “milling”) from a sample, for providing energy to a sample surface as part of reacting a surface-adsorbed precursor or a gaseous precursor, and/or for hardening a deposited layer (e.g., through annealing technique and/or by implanting exogenous atoms into a material using the beam of ions). Embodiments of the present disclosure include methods for using one or more ion beams to process a material sample that is sensitive to thermal gradients and is susceptible to deformation under strain induced by ion beam processing.

As with the electron beam column 107, the FIB column 111 can include electromagnetic optics (e.g., electrostatic lenses, electromagnetic lenses, monochromators, etc.) and apertures configured to shape, focus, defocus, narrow, and direct the beam of ions such that the beam is focused onto the sample 130, in accordance with a set of operating parameters. The operating parameters can include a beam current, a beam energy (e.g., in volts, in electron volts, or the like), a magnification parameter, a scan pattern, a dwell time, and/or one or more pulse parameters. In this way, the example system 100 can function as a FIB to modify portions of the sample 130 and/or to be used for ion-beam assisted removal of material from and/or deposition of material onto the sample 130 (e.g., in coordination with the GIS 115). In another example, multiple layers of the sample 130 can be iteratively removed as part of imaging the cross-section of the sample 130 at multiple positions. This technique, referred to as “slice-and-view,” permits SEM image data to be used as part of 3D reconstruction of the internal features of the sample 130. In the example shown, the sample 130 is disposed in a cryo-holder 131. The cryo-holder can house multiple samples in such a way that reduces exposure to water vapor between a cryogenic freezing system and the vacuum chamber 120, thereby reducing and/or eliminating the formation of ice crystals that can impair sample preparation and imaging. To that end, embodiments of the present disclosure include techniques for processing cryogenically frozen samples to facilitate lamella preparation, as well as “slice-and-view” 3D reconstruction.

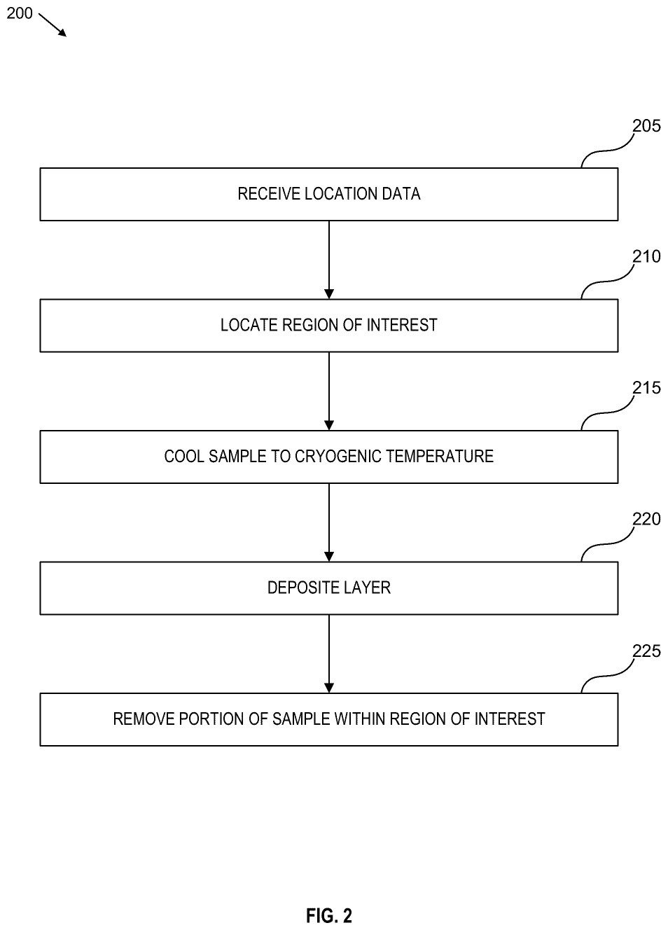

The GIS 115 includes constituent elements that together permit the GIS 115 to generate a gas stream including the precursor and to direct the gas stream into the vacuum chamber. The components of the GIS 115 can include a carrier gas inlet, a nozzle 119, and a conduit fluidically coupling the nozzle 119 and a precursor reservoir 117. The precursor reservoir 117 can include a substantially non-reactive container (e.g., a ceramic crucible, PTFE enclosure, a non-reactive metal or alloy, or the like) that is at least partially exposed to the conduit. In this way, vapor generated from a precursor disposed in the precursor reservoir 117 can be directed toward the nozzle and into the vacuum chamber (e.g., by pressure-driven flow induced by a pressure gradient relative to the vacuum of the vacuum chamber). In some embodiments, the GIS 115 includes a carrier gas inlet, fluidically coupled with the nozzle 119 via the conduit. In this way, the precursor can be entrained in a flow of carrier gas and directed toward the nozzle and into the vacuum chamber. Additionally and/or alternatively, the precursor can include a gas at standard conditions and can be introduced to the GIS 115 via a gas inlet provided as part of the GIS 115. As described in more detail in reference to FIG. 2, the precursor introduced via the GIS 115 can include a metal and/or an organometallic compound. The precursor can be well suited for deposition of a metal layer onto the sample 130, in which the decomposition of the precursor or other reaction and/or modification can be activated by energy provided using an ion beam and/or an electron beam. Examples of precursors include, but are not limited to, platinum containing precursors (e.g., (methylcyclopentadicnyl)trimethyl platinum) and tungsten containing precursors (e.g., tungsten hexafluoride or W(CO)₆).

Analogous to the energies described in reference to the electron beam, above, the ion beam energy can be selected (e.g., by a user, by an algorithm initiated by a user, and/or automatically without user intervention). In some embodiments, additional and/or alternative precursor decomposition mechanisms (e.g., surface activation and/or secondary electron reemission) can be used as a mechanism for precursor decomposition, thereby allowing the ion beam energy to be determined based at least in part on a relationship between beam energy, sample material properties, and the energetic characteristics of the precursor deposition reaction mechanism. Advantageously, ion beam-induced deposition can elicit relatively high yields, in comparison to electron beam-induced deposition, based at least in part on the combined effect of multiple energy transfer pathways.

The operation of one or more components of the example system 100 can be coordinated by control circuitry, in accordance with machine-executable instructions (e.g., software, firmware, etc.) that can be stored in machine-readable storage media and/or received from external systems via wired and/or wireless communication techniques (e.g., over a WiFi or Bluetooth link). To that end, components of the example system 100 can be automated (e.g., operating without human intervention), pseudo-automated (e.g., operating with limited human intervention to initiate operations, analyze output and confirm, or the like), or manually operated (e.g., where individual operations of the example system 100 are performed and/or coordinated by a human user). In an illustrative example, the sample stage 125 can be mechanically coupled with automated stage controls 127 that permit the sample 130 to be reversibly tilted relative to the beam axes A and B, such that the surface of the sample is oriented at a particular angle relative to a given beam axis during operation of the corresponding charged particle beam source. In this way, the operation of a given beam source can be coordinated with the operation of the stage controls 127. In another example, one or more sample-handling components can be provided as part of example system 100 that facilitate the processing of cryogenic samples, including as part of an automated or pseudo-automated processing scheme. To that end, a cryo-unit 129 can be provided with a sample handling transfer robot (e.g., including a motorized transfer arm and a multi-sample cassette system) that is configured to reversibly attach to the cryo-sample holder 131 and/or to individual samples. A multi-sample “cryo-shuttle” is shown in FIG. 1 being disposed substantially at the intersection of axes A and B, facilitating 3D reconstruction imaging techniques implementing iterative removal and imaging operations. In some embodiments, the cryo-unit 129 further includes one or more components for cryogenic sample preparation, such as a cooling system to bring a sample to cryogenic temperatures while under vacuum. This is further described in reference to FIG. 2, below. Cryogenic sample processing can be further implemented by including one or more components for thermal management. For example, the sample stage 125 can include a cold reservoir 126. The cold reservoir 126 can include a cold-finger, liquid helium reservoir, or the like, thermally coupled with the sample stage 125 and/or the cryo-holder 131 and configured to remove heat from the sample 130. Further, example system 100 can be provided with a cryo-shield 128 that at least partially encloses an environment of the sample 130. The cryo-shield 128 can attenuate radiative heat losses from the sample 130 and/or can contain loss of sample material based at least in part on sublimation under vacuum.

Some embodiments of the present disclosure omit one or more components of example system 100. For example, one or more of the sources 105 and 110 and/or columns 107 and 111 can be omitted. In an illustrative example, an single-beam FIB system can be configured to perform operations for generating a beam of ions. Similarly, a multi-beam FIB system other than a dual-beam FIB-SEM (e.g., a FIB-Laser system or a FIB-SEM system for which two or more beam axes are not convergently trained on a given region of the sample 130) can include the charged particle sources of the present disclosure.

FIG. 2 is a block flow diagram illustrating an example process 200 for processing a material sample in a charged particle beam system, in accordance with some embodiments of the present disclosure. One or more operations making up the example process 200 can be executed by a computer system or other programmable logic machine, operably coupled with components of a charged particle microscope (e.g., example system 100 of FIG. 1) and/or additional systems or subsystems including, but not limited to, characterization systems, power supply systems, network infrastructure, databases, and/or user interface devices. To that end, operations of example process 200 can be stored as machine executable instructions in one or more machine readable media. A detailed embodiment of example process 200 is described in reference to Example 1, below, for which a sample that is susceptible to thermal deformation was processed into a lamella for further interrogation by a transmission electron microscope (TEM).

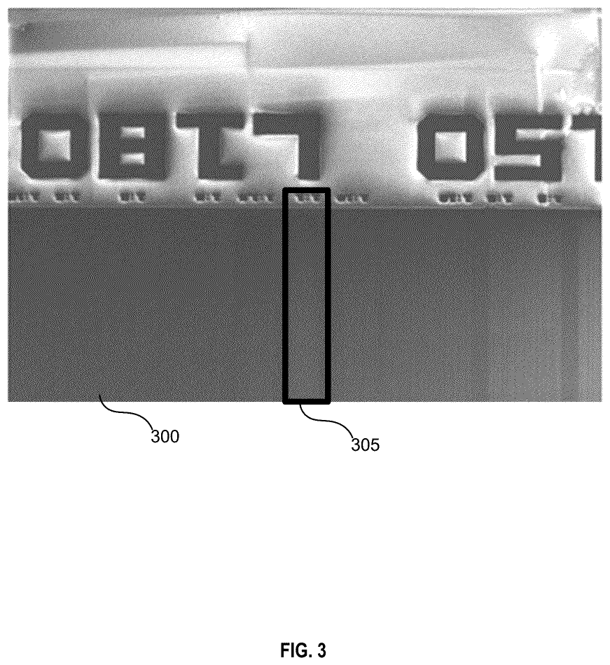

One or more operations of the example process 200 can be repeated, reordered, and/or omitted, for example, as part of preparing a lamella for further interrogation by a high-resolution charged particle microscope, using techniques of the present disclosure. To that end, the operations of example process 200 are described as being performed by a system, where it is understood that the operations can include generating and communicating control signals between a processor or other logic circuitry and electronic or electromechanical elements of the charged particle beam system. The operations of example process 200 are described in the context of a dual-beam system in the interest of clarity, but embodiments of the present disclosure include other charged particle beam systems, such as those systems that are configured with additional and/or alternative particle beam sources (e.g., laser ablation systems, atomic-layer deposition systems, etc.). The example process 200 omits one or more operations that can precede and/or follow one or more operations of example process 200. For example, operations can include drawing and maintaining a vacuum in a vacuum enclosure (e.g., the vacuum chamber 120 of FIG. 1) in which a sample is processed (e.g., the sample 130 of FIG. 1). Additionally, operations can include one or more steps implicated by the processing of cryogenically frozen samples, such as actuating one or more internal components of the charged particle beam system (e.g., “cryo-shutters,” “cryo-box” environmental shields) and/or using internal tools, such as robotic and/or manual sample manipulators to orient a sample surface relative to one or more charged particle beam axes (e.g., axis A and/or axis B of FIG. 1). In contrast to typical approaches for TEM lamella preparation techniques, example process 200 can omit operations for depositing a protective layer by electron beam induced deposition (EBID). As described in more detail in reference to EXAMPLE 1 (FIGS. 3-10D), EBID can induce deformation, shrinkage, and cracking of sample structures that negatively impacts the fidelity of measurements in TEM.

At operation 205, example process 200 includes receiving location data for a sample. The sample can be disposed in the chamber of a charged particle beam system, in preparation for processing operations of the example process 200. The location data can be provided for a sample that is to be processed at another time, for example, as part of a schedule sample pipeline in an automated or semi-automated sample metrology operation (e.g., as part of semiconductor manufacturing). The location data can be based at least in part on computer-aided-drawing (CAD) data describing at least a portion of the sample.

The location data, for example, can describe one or more reference features of a sample, and/or one or more regions of interest of the sample. A region of interest (ROI) can include a feature that is to be removed from the bulk of the material sample (e.g., as a part of a lamella), for examination in a subsequent imaging or microanalysis operation. Locating the ROI, at operation 210 of example process 200, can include navigation to the ROI via a registered motion of the sample stage (e.g., sample stage 125 of FIG. 1) in reference to a position on the sample, visible at relatively low magnification (e.g., under optical microscopy and/or low magnification and low current SEM). In another example, relative location data can describe the position of the ROI relative to external frames of reference. Where a charged particle beam system uses a standardized sample size and holder configuration, a reference point can be defined with a position vector defining a registered motion of the sample stage. The terminus of the vector being a point that disposes the ROI in a position that substantially intersects the axis of a charged particle beam system (e.g., axes A and/or B of FIG. 1).

In an illustrative embodiment, the sample can include one or more integrated circuit elements, such as metal layer interconnects, semiconductor devices, or the like, organized in a multilayer CMOS structure on a wafer, as would be produced in a semiconductor manufacturing process. In this example, the location data can describe a location (e.g., a relative location, in reference to one or more reference features) of a semiconductor device or group of devices that are to be the subject of metrology assessment, relative to a larger feature that is visible at lower magnification (e.g., a die anchor). In some cases, the relatively larger feature can be visible while the features in the ROI can be invisible at the lower magnification setting (e.g., the feature can be present and visible on an exterior surface of the material sample and the ROI can be internal to the material sample).

At operation 215, example process 200 includes cooling the sample to a cryogenic temperature. In general, the term “cryogenic” can indicate a relatively broad range of temperatures below about −150° C. (about 120 K). As described in more detail in reference to EXAMPLE 1, below, processing material samples for charged particle beam interrogation at cryogenic temperatures provides advantages including preserving fabricated geometries of thermally sensitive constituent materials (e.g., photoresist layers, anti-reflective coatings, etc.). Embodiments of example process 200, therefore, include cooling material samples to temperatures about −150° C. For example, samples can be cooled to about about −160° C., about −170° C., about −180° C., about −190° C., about −200° C., or the like, including fractions, interpolations, and subranges thereof. Below-190 degrees Celsius, operational demands for cooling samples and maintaining low temperatures may exceed the capabilities of most charged particle beam systems. Above-150 degrees Celsius, benefits of cryogenic processing, such as the absence of crystalline ice, can be impaired. In some embodiments, the charged particle beam system can be provided with a cryo-stage (e.g., stage 125 of FIG. 1), including a cold reservoir, where the material sample can be relatively warmer than the cold reservoir by about 20° C. In this way, the cold reservoir can absorb heat from the material sample that can be generated by irradiation by photons, ions, electrons, or the like.

Cooling at operation 215 can proceed via several different techniques, including but not limited to plunge freezing, high-pressure freezing, or the like. In some embodiments, chemically sensitive material samples, such as those that are sensitive to oxidation, can be cooled in an inert atmosphere, such as a dry sample preparation enclosure or otherwise in a system configured to process samples under a vacuum or in the absence of reactive gases. In an illustrative example, a wafer sample can be introduced to an inert environment of a glove box prior to cooling and stored in a cryogenic sample holder (e.g., cryo-holder 131 of FIG. 1) prior to being removed from the glove box. In some embodiments, the sample is cooled within a vacuum enclosure of a charged particle beam system. For example, a cryogenic electron microscope system can include one or more components that facilitate the processing of samples at cryogenic temperatures, including cooling and sectioning (e.g., cryo-unit 129 of FIG. 1). In this way, a material sample can be introduced to the charged particle beam system at substantially ambient temperature, and can be brought to cryogenic temperatures within the charged particle beam system.

In some embodiments, operation 215 can precede at least a portion of the steps included in operation 205 and/or operation 210. For example, a sample can be introduced into a charged particle beam system configured for cryogenic sample preparation, and operation 215 can be implemented prior to coupling a cryogenic sample holder with a sample stage and prior to navigating the stage to a position corresponding to an ROI of the sample. Alternatively, operation 205 and operation 210 can be implemented based at least in part on CAD data or other data (e.g., referential position information) that permits navigation commands to be developed prior to introduction of the sample to the sample stage of the charged particle beam system. For example, an optical microscope can be used to generate location data in reference to a feature on a sample surface, prior to introducing the sample to a cryogenic sample preparation system.

At operation 220, example process 200 includes depositing a layer over at least a portion of the material sample. As described in more detail in reference to EXAMPLE 1, below, operation 220 can include ion-beam induced deposition (IBID), electron beam induced deposition (EBID), photon induced deposition, and/or decomposition of gaseous precursors delivered to the material sample (e.g., using GIS 115 of FIG. 1). Various layer compositions are contemplated, including but not limited to those including metals as well as nonmetal constituents. For example, platinum containing layers, tungsten containing layers, among others, are contemplated. In some embodiments, organo-metallic compounds including platinum are used to deposit a platinum layer overlying at least a portion of the sample. Deposition can proceed via a precursor delivered to the surface of the sample using a GIS system (e.g., GIS 115 of FIG. 1) and/or by other means, including but not limited to physical vapor deposition, plasma sputtering, or the like. In some embodiments, an ion beam (e.g., FIB) can be directed toward at least a portion of the sample surface as an approach to augmenting one or more physical properties of the sample in and/or near the ROI. In an illustrative example, the ion beam can be use to harden a region of the sample. In this context, sample hardening can refer to a post-deposition exposure to a FIB scan pattern for a period of time (e.g., a rectangular, square, circular pattern, etc., for a period of time from about 0.1 seconds to about 100 seconds) by which the deposited layer can be annealed or otherwise cured based at least in part on exposure to the ions of a FIB. In an example embodiment, a GIS system can be used to introduce a platinum precursor that is decomposed and condensed into a platinum layer overlying at least a portion of the sample, after which a rectangular scan pattern can be used to cure the platinum layer using a FIB at an energy of about 30 kV and about 1.0-1.5 nA for a period of time. In some embodiments, multiple iterations of curing are employed to reduce thermal effects that can affect the stability of underlying structures of the sample.

Advantageously, example process 200 permits one or more operations of conventional processing to be omitted, such as a first deposition operation using an electron beam, which is conventionally used to mark the ROI for subsequent IBID layer formation. As described in reference to EXAMPLE 1, below, omitting EBID processing preserved as-fabricated geometries of temperature sensitive components (e.g., carbon-containing photoresist patterns and anti-reflective coatings) of material samples. As a further advantage, the operations of example process 200 permit cryogenic processing of samples without a preliminary EBID deposition of a relatively thin first layer, thereby sacrificing the benefit to locating the ROI for subsequent FIB processing, at least in part by permitting navigation to the ROI based on the location data describing a relative location of the ROI. In this way, example process 200 is well suited to automation, as well, at least in part because the location of the ROI in the sample can be defined in a way that is agnostic to operations of example process 200 (e.g., the location can be extrinsically defined).

At operation 225, example process 200 includes removing a portion of the sample. Operation 225 can include one or more sub-operations for preparing a lamella for subsequent interrogation by a charged particle beam system. The lamella can include at least a portion of the ROI. For example, operation 225 can include one or more sub-operations including FIB-milling or other removal steps, such as delayering, inverted lamella-preparation, or the like, such that a sample can be prepared for which at least a portion of the sample is substantially transparent to electrons, while remaining at cryogenic temperatures. Advantageously, operation 225 can produce a sample with improved geometric fidelity relative to an as-fabricated material, relative to conventional sample preparation techniques executed at room temperature, as well as those executed at least partially or entirely at cryogenic temperatures, as described in more detail in reference to EXAMPLE 1, below.

In some embodiments, example process 200 includes multiple iterations of operation 225. For example, the removal of sample material can follow a procedure for iterative removal and imaging on a layer-by-layer basis, also referred to as “slice-and-view.” Slice-and-view procedures typically include removing a relatively thin layer of sample material with a subsequent imaging procedure that permits, among other things, improved end-pointing at a given point before or in the ROI (e.g., a line-indicated-termination process) and/or 3D reconstruction of internal structures of the sample. In line with slice-and-view procedures, the FIB can be used to progressively reveal a cross surface in the sample, advancing the surface toward the ROI. Further, an initial trench can be formed by the FIB at a position that is offset from the ROI, the offset being defined, based at least in part on the location data. For example, where the ROI is defined by a set of coordinates in reference to a feature on the sample, the offset can be defined in reference to the set of coordinates. Incremental volumes of the sample can be removed, advancing toward the ROI, until a portion of interest is revealed. In some embodiments, the initial trench is formed at a nonzero angle relative to the surface of the sample, such as an angle between zero degrees and about 90 degrees, which can attenuate the severity of milling artifacts (e.g., curtaining). Advantageously, such layer-by-layer procedures, including those for which the angle of incidence of the FIB is between about 0 degrees and about 90 degrees, provide improved localization of a cross surface that reveals features of interest of the ROI, for subsequent lamella formation operations.

### EXAMPLE 1: CRYOGENIC SAMPLE PREPARATION

Photoresist (PR) layers tend to deform and/or shrink during conventional Transmission electron microscopy (TEM) sample preparation method that includes Scanning Electron Microscope (SEM) processing and Focused Ion Beam (FIB) processing. For example, temperature changes during sample preparation can cause deformation and shrinkage with PR profiles, which, in turn, reduce the value of TEM-based metrology as an accurate measure of fabrication fidelity. To that end, sample preparation was performed under cryogenic temperature conditions using a cryo-FIB to assess the influence of cold-temperature processing on deformation and shrinkage in multilayer semiconductor samples. TEM sample preparation processes were performed under different conditions, targeting different heat sources that could be potential causes of deformation and/or shrinkage. Results of the different test conditions, assessed via TEM microscopy, revealed that characteristic dimensions of PR patterns, such as a line/space ratio, were closest to corresponding target values (e.g., line/space ratio of 1:1) and bottom anti-reflective coating (BARC) shrinkage was lowest with sample preparation under cryo-FIB condition. These improvements to sample preparation techniques, demonstrating preservation of PR profiles in −170° C. TEM sample preparation condition using cryo-FIB, represent a significant step forward relative to the current state of the art.

The technique using Scanning Electron Microscope (SEM) and Focused Ion Beam (FIB) has been widely adopted for Transmission electron microscopy (TEM) sample preparation method. However, deformation and shrinkage profiles significantly limit the application of conventional TEM sample preparation method using SEM and FIB to metrology of thermally sensitive materials. In an illustrative example, polymeric photoresist materials (e.g., KrF class of polymeric photoresist materials, other EUV photoresists, etc.) can be fragile and sensitive to temperature change during processing. Localized heating during the TEM sample preparation, such as from electron beam heating during EBID, can deform and/or shrink PR materials. In this way, patterned PR layers can be deformed, making metrology ineffective. These issues are typically addressed by alternative techniques, such as atomic layer deposition (ALD) coating or ink coating to reduce deformation, each of which introduce added complexity to sample preparation systems. In contrast, embodiments of the present disclosure perform sample preparation in cold temperature using cryo-FIB to reduce deformation and shrinkage issues, while also obviating the need for additional sample preparation subsystems. To that end, improved sample preparation using cryo-FIB was validated by TEM sample preparation processes performed under four different conditions: room temperature FIB process including SEM deposition; room temperature FIB process without SEM deposition; partial cryo-FIB process without SEM deposition; and full cryo-FIB process without SEM deposition.

TEM sample preparation was operated with Thermo Fisher Scientific Helios G4 UX cryo-MAT. The instrument employed for the reported trials included a dual beam charged particle beam system, as described in reference to FIG. 1, combining an SEM and a FIB provided with cryogenic material processing sub-system. The cryo-mat system included a cold trap (e.g., cold-reservoir of FIG. 1) and cold stage providing a cold temperature of about −190° C. Contamination of the stage was addressed by providing at least a 20° C. temperature difference between the stage and the trap. Therefore, for cryo-condition, the stage temperature was regulated at about −170° C., and the trap temperature at about −190° C. for the trap to absorb carbon contamination (e.g., from the environment of the vacuum about the sample stage). A liquid nitrogen gas flow, introduced via the sample stage and/or cold trap, was used to modulate the temperature of the cryo-assembly.

After making TEM samples using Helios G4 cryo-MAT, TEM images were analyzed using a Thermo Fisher Scientific Talos F200X system. TEM analysis was conducted at ambient temperature. To that end, the stage temperature was set to about 20° C. before removing lamella samples from the charged particle beam system. When cooling the sample and when returning the sample to ambient temperature, the temperature was changed gradually, motived at least in part to avoid rapid temperature changes with the sample and to reduce thermal strain.

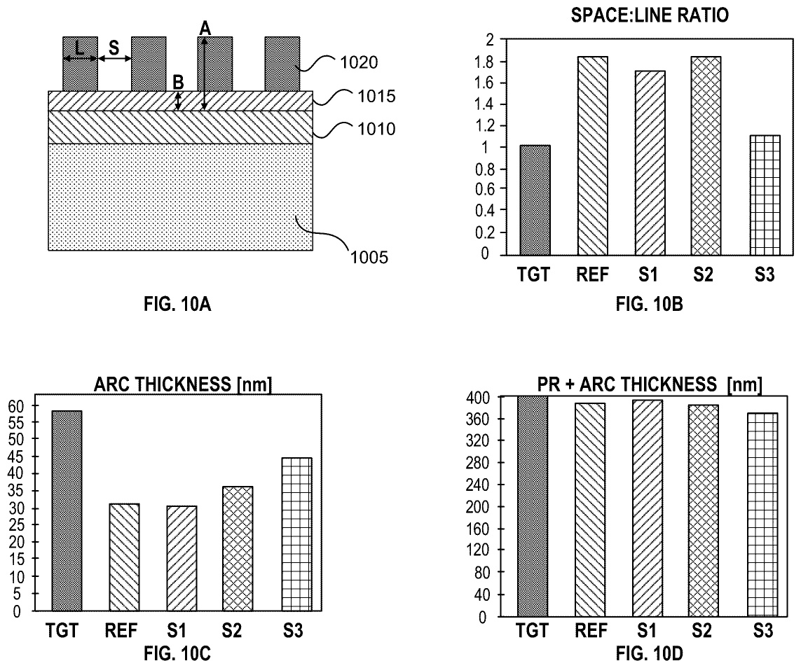

Samples used in the validation study included a KrF PR pattern 300 obtained from a fab service. The TEM sampling area 305 was performed in the L180 1:1 ratio as shown in FIG. 3 in an electron micrograph. The term L180 reflects that the Critical Dimension (CD) of line and space features of the pattern, illustrated in FIG. 10A, are each 180 nm wide. Four different sample preparation schemes were undertaken compare PR profiles resulting from different FIB processes, as described in Table 1. The tests are referred to as “reference,” “split 1,” “split 2,” and “split 3” in the forthcoming discussion.

TABLE 1
Test Conditions

| | SEM | | FIB | |
|---|---|---|---|---|
| TEST | DEP. | FIB DEPOSITION | PREP. | TEM |
| REF | ROI Pt | ROI Pt at AMBIENT TEMP | AT | AT |
| | | (AT) | | |
| SPLIT 1 | N/A | BLIND ROI Pt at AT | AT | AT |
| SPLIT 2 | N/A | BLIND ROI Pt at AT | −170° C. | AT |
| SPLIT 3 | N/A | GIS Pt at −170° C. | −170° C. | AT |

The reference test employed a conventional TEM sample preparation method under ambient temperature conditions. The reference test included SEM deposition, done with a rectangular pattern for region of interest (ROI) using a platinum deposited layer. In a conventional method, SEM deposition serves both to protect the ROI before FIB processing and to mark ROI area for navigation by the FIB. After SEM deposition, a material was deposited by FIB overlying at least part of the SEM deposition area and followed by FIB processing at room temperature. Typical FIB processing includes bulk milling, bottom milling, U-cut, lamella lift-out, grid attachment, thinning, and low kV cleaning. The overall SEM and FIB conditions are summarized in Table 2.

TABLE 2
Charged Particle Beam Conditions

| OPERATION | CONDITIONS |
|---|---|
| SEM BEAM & DEPOSITION | 2 kV, 0.1 nA/2 kV, 0.8 nA |
| FIB BEAM & DEPOSITION | 30 kV, 90 pA |
| FIB BULK MILLING | 30 kV, 9.9 nA |
| FIB THINNING | 30 kV, 0.44 nA/90 pA |
| FIB LOW kV CLEANING | 5 kV, 63 pA |

The split 1 test was also conducted at ambient temperature conditions. Split 1 differed from the reference in that split 1 omitted the SEM deposition process. Without a SEM-deposited layer to mark the ROI, navigation to the ROI for FIB deposition employed location data describing a relative position of the ROI in reference to a marking on the sample that was visible at low magnification (referred to as “blind”). In this context, low magnification refers to a magnification of 1,000 × or less (e.g., about 350 ×). The split 1 test conditions examined the effect of SEM deposition in room temperature and comparing the resulting PR pattern to that remaining after following the reference procedure.

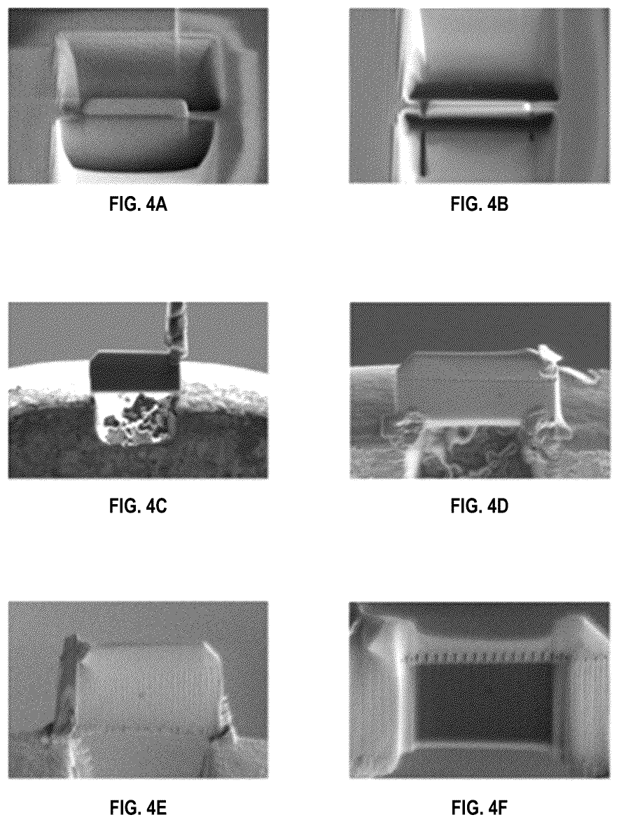

Comparison of the reference and split 1 tests revealed that the SEM deposition operation(s) cause PR shrinkage and impair the fidelity of CD measurements. For target protection, the eucentric height of the stage was adjusted to about 20 μm away in x-axis from the ROI area. The deposition box pattern was as well drawn 20 μm away from the center for the split 1 FIB deposition operation. This process was also followed in the split 2 test for FIB deposition. After the blind ROI FIB deposition, subsequent operations reproduced the reference test. The overall process of split 1 test is shown in FIGS. 4A-4F.

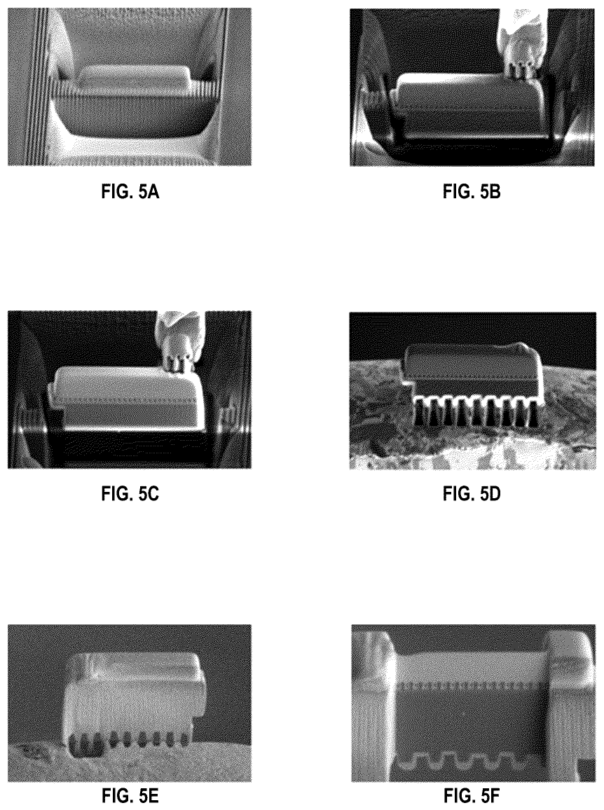

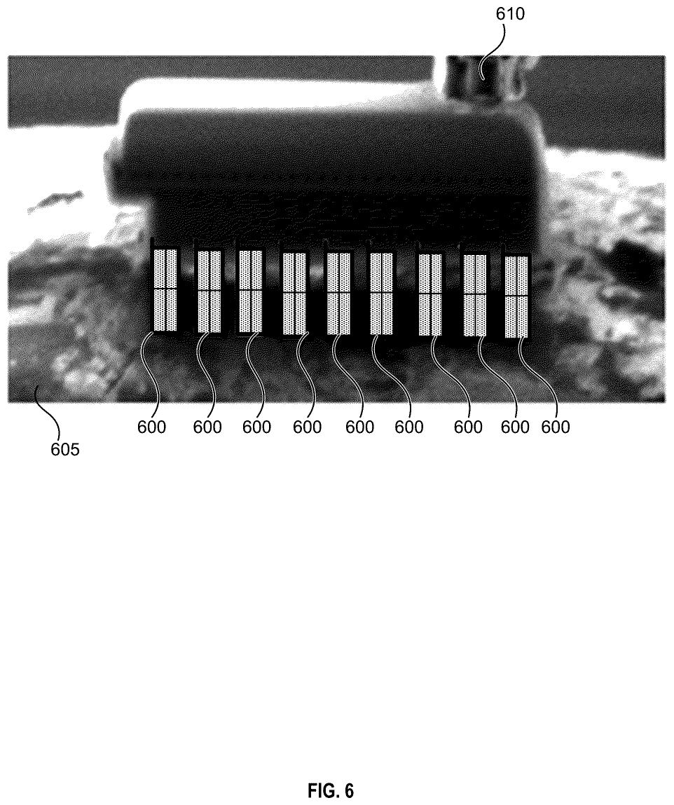

The split 2 test was conducted as a partial cryo-FIB process. The overall process of split 2 test is shown in FIGS. 5A-5F. The blind Pt FIB deposition substantially reproduced that of split 1. The temperature settings for the cryo-FIB process were then implemented. The stage and the cold trap temperature were set to about −170° C. and about −190° C., respectively. The gas flow of liquid nitrogen was controlled to maintain the temperature substantially at set point. FIB processing began with bulk milling. Subsequent to U-cut, deposition overlying at least part of the ROI was undertaken using FIB and GIS injection, as part of lamella lift-out and grid attachment. The Gas Injection System (e.g., GIS 115 of FIG. 1) free attachment method was employed, as shown in FIG. 6. The FIB conditions for GIS-free attachment are shown in Table 3. Instead of ROI deposition using SEM, a regular cross-section (RCS) scanning pattern 600 was used for attachment method at about −170° C. The redeposition of material from a sample 605 from the milling pattern 600 enables GIS-free attachment of the manipulator 610.

TABLE 3
FIB conditions for GIS-free attachment

| OPERATION | FIB CONDITIONS |
|---|---|
| NEEDLE ATTACHMENT | 30 kV, 41 pA (RCS mill) |
| WELD TO GRID | 30 kV, 0.75 nA (RCS mill) |

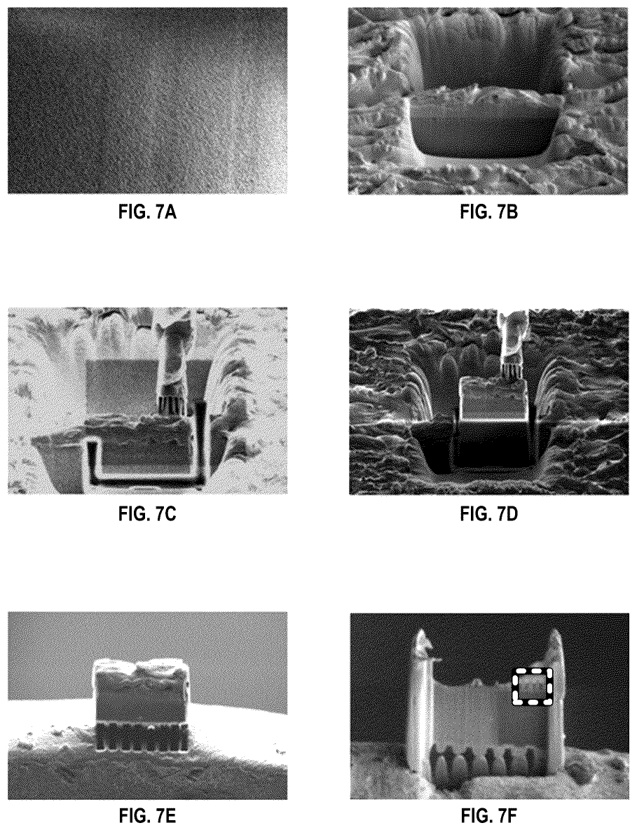

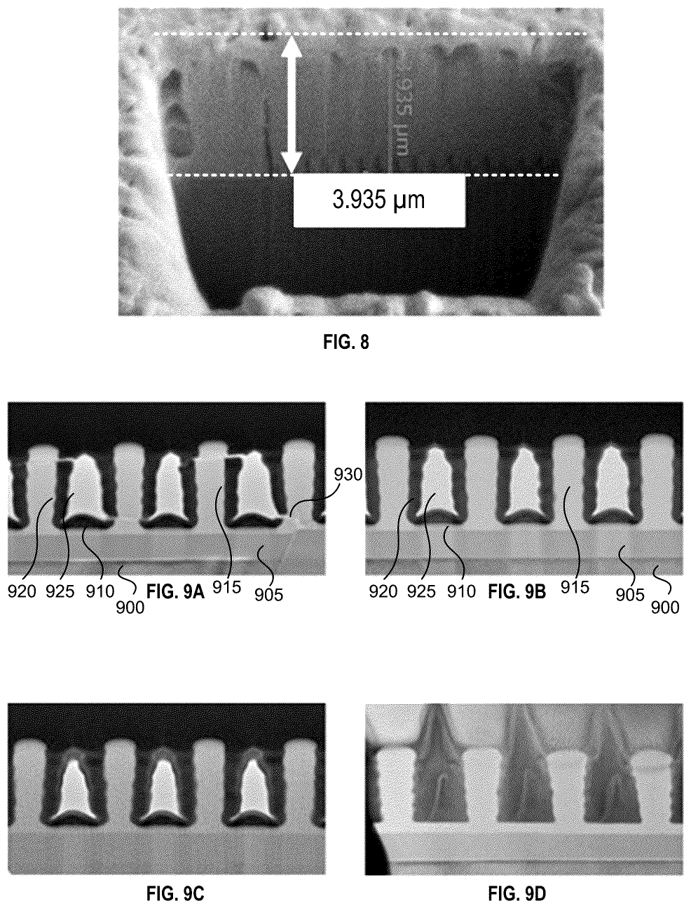

The split 3 test was conducted as a cryo-FIB process. The overall process of split 3 test is shown in FIGS. 7A-7F. Since ROI deposition is not available in −170° C., GIS Pt deposition was done on the overall sample, shown in FIG. 7A. The GIS system was opened for 5 minutes at a 6.4 mm working distance from the sample surface. In this condition, the depth of deposition was measured as 3.935 μm, as shown in FIG. 8. After deposition, the split 3 process reproduced the split 2 test. As in the split 2 test, ROI-free attachment method was employed for needle and lamella attachments. The TEM image in FIG. 9D was obtained in the region of the sample indicated in dashed black and white lines in FIG. 7F.

The TEM images of the samples obtained from the above FIB processes are shown in FIGS. 9A-9D. Some differences were observed between the TEM images. The images show a multilayer structure including a substrate 900, an intermediate layer 905, an anti-reflective coating 910, multiple PR 915 profiles, and platinum 920 disposed between the PR 915 profiles. Cracks 930 were observed the sample from the reference test which included SEM deposition in the beginning of FIB process, as shown in FIG. 9A. This represents that the 2 k V 0.8 nA SEM deposition induces stresses that detrimentally affect PR 915. The absence of crack 930 formation in the three split tests implicate a role of SEM deposition in sample cracking. Additionally, voids 925 were were observed in the platinum 920 for split 1 (FIG. 9B) and split 2 (FIG. 9C), but not in split 3 results, shown in FIG. 9D. From this, it was understood that Pt 920 deposition is more prone to void 925 formation at room temperature than at cryogenic temperatures. Further, the images in FIGS. 9A-9D also reveal the anti-reflective coating (ARC) 910 is the flattest and thickest in the sample prepared in full cryo-FIB process. This indicates that ARC 910 shrinkage is also affected by the temperature employed during FIB processing.

The KrF PR pattern configuration of the tested sample is shown in FIG. 10A, including schematic representations of the substrate 1005, the intermediate layer 1010, the ARC 1015, and the PR 1020 profiles, shown in reference to FIGS. 9A-9D. Target values for measurement are provided in Table 4. The target value for PR thickness including ARC was 460 nm, and the target ARC thickness was 58 nm. Since the TEM sampling area was performed in L180 1:1, the target line and the space CD were 180 nm each.

TABLE 4
TARGET MEASUREMENTS REFLECTED IN FIGS. 10A-10D

| | PR + ARC | ARC | SPACE:LINE RATIO |
|---|---|---|---|
| | [A] | [B] | [C] = S:L |
| TARGET | 460 nm | 58 nm | 1:1 |

The PR profiles of the tested samples were measured using image processing software. The measured parameters were space-line ratio [C], ARC thickness [B], and PR thickness including ARC [A], as shown in FIGS. 10B-10C, respectively. The data was collected in three different PR profiles, and the data shown in the graph represents an average value of the measurements. TEM results showed that PR space/line ratio was closest to the target which is the sample's fabricated space/line ratio (1:1) with sample preparation in accordance with the split 3 cryo-FIB condition. This indicates that the horizontal dimension of PR was affected by the temperature during the FIB process. As shown in the FIG. 10B, S:L was comparable between reference, split 1, and split 2 tests. This indicated that FIB deposition in room temperature affected the horizontal line shrinkage. Also, it was shown that ARC shrinkage decreased under split 3 cryo-FIB conditions. As shown in FIG. 10C, ARC thickness was closest to the target under split 3 cryo-FIB conditions. The second thickest in ARC was the sample made with partial cryo-FIB process. From this, it can understood that the temperature during FIB processing plays a role in ARC shrinkage. Finally, the results of PR+ARC measurements reveal that PR layers do not shrink appreciably normal to the surface of the layer, with all four test conditions producing comparable values in FIG. 10D. From this, it is understood that the temperature effect on PR is at least partially limited to a transverse deformation that increases the S:L ratio significantly.

The technique using SEM and FIB has been widely adopted for TEM sample preparation method, but the combined SEM/FIB technique negatively affects the reliability of TEM measurements of as-fabricated structures. PR profiles tend to have deformation and shrinkage with conventional TEM sample preparation method using SEM and FIB. Sample preparation at cryogenic temperatures using cryo-FIB revealed temperature dependency of the deformation/shrinkage effect. TEM results showed that PR S:L ratio was closest to the target S:L ratio (1:1), and ARC shrinkage was significantly lower under split 3 cryo-FIB conditions. To improve the reliability of TEM measurements in temperature sensitive materials, therefore, a low-magnification navigation technique, in reference to location data for a given sample, followed by FIB processing under cryogenic conditions, appears to be better suited than SEM EBID deposition to mark an ROI.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on charged particle systems, and dual-beam systems in particular, these are meant as non-limiting, illustrative embodiments.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For dimensional values, such as diameters, lengths, widths, or the like, the term “about” can be understood to describe a deviation from the stated value of up to +10%. For example, a dimension of “about 10 mm” can describe a dimension from 9 mm to 11 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A method, comprising:
receiving location data for a material sample;
locating a region of interest (ROI) of the material sample in reference to the location data;
cooling the material sample to a cryogenic temperature;
depositing a layer over at least a portion of the ROI at the cryogenic temperature; and
removing a portion of the material sample at the cryogenic temperature.

2. The method of claim 1, wherein the material sample comprises a photoresist.

3. The method of claim 2, wherein the material sample comprises an anti-reflective coating (ARC) disposed between the photoresist and a substrate.

4. The method of claim 1, wherein depositing the layer comprises:
introducing a precursor into an environment of the material sample, the precursor comprising a metal constituent; and
decomposing the precursor using a focused beam of ions.

5. The method of claim 4, wherein the metal is platinum or tungsten.

6. The method of claim 5, wherein the precursor is (methylcyclopentadienyl)trimethyl platinum.

7. The method of claim 1, wherein the location data comprise computer-aided-drafting (CAD) data describing at least a portion of the material sample and a location of the ROI.

8. The method of claim 1, further comprising hardening the layer using a focused ion beam.

9. The method of claim 1, wherein locating the ROI comprises generating an optical microscope image of the material sample.

10. The method of claim 1, wherein locating the ROI comprises generating secondary electron detector data at a relatively low magnification setting of an electron beam column, wherein the relatively low magnification setting of the electron beam column corresponds to a magnification setting and a beam current setting that together render visible a reference feature in the location data.

11. The method of claim 1, wherein the cryogenic temperature is about −170° C.

12. The method of claim 1, further comprising maintaining a temperature differential between the material sample and a cold reservoir, such that the material sample is relatively warmer than the cold reservoir by about 20° C.

13. The method of claim 1, wherein removing the portion of the material sample comprises milling the material sample to form a lamella.

14. The method of claim 1, further comprising generating an image of a cross-surface of the material sample using a charged particle microscope, the cross surface being at an angle relative to a lateral surface of the sample.

15. The method of claim 14, wherein the image is generated while the material sample is at the cryogenic temperature.

16. A system, comprising:
a vacuum chamber;
an electron microscope column operably coupled with the vacuum chamber;
a focused ion beam column operably coupled with the vacuum chamber;
a sample stage disposed in the vacuum chamber;
a cooling system, thermally coupled with the sample stage and configured to cool the sample stage to cryogenic temperatures; and
one or more non-transitory machine-readable storage media, operably coupled with the system, storing instructions that, when executed by one or more components of the system or other machine(s), cause the system to perform operations including:
receiving location data for a material sample;
locating a region of interest (ROI) of the material sample in reference to the location data;
cooling the material sample to a cryogenic temperature;
depositing a layer over at least a portion of the ROI at the cryogenic temperature; and
removing a portion of the material sample within the ROI at the cryogenic temperature.

17. The system of claim 16, wherein locating the ROI follows cooling the material sample to the cryogenic temperature.

18. The system of claim 16, wherein depositing the layer comprises:
introducing a precursor into an environment of the material sample, the precursor comprising a metal constituent; and
decomposing the precursor using a focused beam of ions.

19. The system of claim 16, wherein locating the ROI comprises generating secondary electron detector data at a relatively low magnification setting of an electron beam column, wherein the relatively low magnification setting of the electron beam column corresponds to a magnification setting and a beam current setting that together render visible a reference feature in the location data.

20. The system of claim 16, wherein locating the ROI comprises executing a registered movement of the sample stage, based at least in part on the location data, wherein a location of the ROI is described in reference to a feature of the material sample.
